(19) United States
(12) Patent Application Publication
(10) Pub. No.: US 2026/0156980 A1
(43) Pub. Date: Jun. 4, 2026

(54) LIGHT-EMITTING DEVICE HAVING A CAVITY STRUCTURE AND METHOD OF MANUFACTURING THE SAME

(71) Applicant: Korea Photonics Technology Institute, Gwangju (KR)

(72) Inventors: Jong Hyeob BAEK, Daejeon (KR); Yung Ryel RYU, Pyeongtaek-si Gyeonggi-do (KR); Seong Ran JEON, Gwangju (KR)

(73) Assignee: Korea Photonics Technology Institute, Gwangju (KR)

(21) Appl. No.: 19/448,357

(22) Filed: Jan. 14, 2026

Related U.S. Application Data
(63) Continuation of application No. PCT/KR2025/016011, filed on Oct. 13, 2025.

(30) Foreign Application Priority Data
Dec. 4, 2024 (KR) 10-2024-0178465

(51) Int. Cl. H10H 20/841; H01S 5/183; H10H 20/825

(52) U.S. Cl. CPC H10H 20/841; H01S 5/18311; H01S 5/18361; H10H 20/825

(57) ABSTRACT

Disclosed are a light emitting device having a cavity structure and a method of manufacturing the same. According to one embodiment of the present disclosure, a light emitting device including nitride and oxide semiconductors and having a cavity structure, and a method of manufacturing the same, are provided. Because the light-emitting device includes nitride and oxide semiconductors and has a cavity structure, the light-emitting device has high luminous efficiency and outputs light with improved straightness.

### CROSS-REFERENCE TO RELATED APPLICATION

This is a continuation of International Application No. PCT/KR2025/016011 filed on Oct. 13, 2025, which claims priority, pursuant to U.S. patent law Section 119(a) (35 U.S.C. § 119(a)), to Korean Patent Application No. 10-2024-0178465 filed in Korea on Dec. 4, 2024, the entire contents of all of which are incorporated herein by reference.

This patent is based on research results carried out with the support of the Korea Evaluation Institute of Industrial Technology (KEIT), funded by the Government of the Republic of Korea (Ministry of Science, ICT and Future Planning) in 2014 (Project Unique No.: 1711017525; Subproject No.: 10041878; Program Name: Core Technology Development for the Electronic Information Device Industry; Project Title: Development of LED optical device processes and standard analysis technology with 75% power conversion efficiency), and research results supported by the Korea Institute for Advancement of Technology (KIAT), funded by the Ministry of Trade, Industry and Energy of the Republic of Korea in 2020 (Project Unique No.: 1415170397; Subproject No.: N0001886; Program Name: Infrastructure Establishment for System Industry Technology Development (R&D); Project Title: Infrastructure Establishment Project for Strengthening Global Competitiveness of the Photonic Convergence Industry).

### BACKGROUND

### 1. Technical Field

The present embodiment relates to a light-emitting device having a cavity structure and a method of manufacturing the same.

### 2. Related Art

Contents described in this part merely provide background information of the present embodiment, and do not constitute a conventional technology.

A light-emitting diode is an inorganic light source and is widely used in various fields, such as display devices, vehicle lamps, and general lighting. Light-emitting diodes have advantages of a long lifespan, low power consumption, and a fast response speed, and thus are rapidly replacing conventional light sources.

In general, a light-emitting diode can output various colors by mixing blue, green, and red light. A light-emitting diode includes a plurality of pixels to implement various images or colors, and each pixel includes blue, green, and red sub-pixels. A color of a particular pixel is determined based on the colors of the sub-pixels, and an image may be implemented by a combination of these pixels.

Conventional light-emitting diodes have typically been manufactured based on nitride semiconductors. Nitride semiconductor-based light-emitting diodes have relatively superior luminous efficiency compared to those made of other conventional materials.

However, conventional nitride semiconductor-based

light-emitting diodes structurally include the following problems. When an indium content in an active layer that generates light increases, luminous efficiency of a nitride semiconductor-based light-emitting device rapidly decreases. This is because nitride semiconductors have different lattice constants, and internal stress tending to compress or expand occurs due to differences in lattice constants.

Due to these problems, conventional nitride semiconductor-based light-emitting diodes have had the inconvenience of relatively low luminous efficiency.

### SUMMARY

An object of one embodiment of the present invention is to provide a light-emitting device including nitride and oxide semiconductors and having a cavity structure, and a method of manufacturing the same.

According to one aspect of the present invention, a light-emitting device comprises: a substrate; a buffer layer formed on the substrate; a first reflector implemented on the buffer layer and composed of a plurality of distributed Bragg reflector (DBR) pairs; an n-type cladding layer deposited on an upper surface of the first reflector and implemented with a semiconductor material doped with an n-type dopant to provide electrons; an active layer deposited on the n-type cladding layer and generating light by recombining provided electrons and holes; a p-type semiconductor layer deposited on the active layer and providing holes to the active layer; a second reflector implemented on the p-type semiconductor layer and composed of a plurality of DBR pairs; a first electrode electrically contacting the buffer layer to supply power to the n-type cladding layer; a second electrode formed on the second reflector to supply power to the p-type semiconductor layer; and a passivation layer applied to a side surface and/or an upper surface of each constituent of the light-emitting device to protect each constituent from the outside.

According to one aspect of the present invention, the light-emitting device further comprises a protective layer deposited on the p-type semiconductor layer to protect the p-type semiconductor layer from an external environment.

According to one aspect of the present invention, the p-type semiconductor layer comprises: a p-type cladding layer deposited directly on the active layer and implemented with a semiconductor material doped with a p-type dopant to provide transferred holes to the active layer; and a p-type oxide layer deposited on the p-type cladding layer to mitigate internal stress that may occur between the active layer and the p-type cladding layer and to improve a hole transfer rate.

According to one aspect of the present invention, the p-type cladding layer is implemented with p-type GaN, p-type InGaN, p-type AlGaN, or p-type AlInGaN, or a combination thereof.

According to one aspect of the present invention, the p-type oxide layer is implemented with zinc oxide (ZnO), or an oxide including zinc (Zn) and Group II elements and Group VI elements in the periodic table.

According to one aspect of the present invention, a method of manufacturing a light-emitting device comprises: a first forming process in which a buffer layer is formed on a substrate; a first implementing process in which a first reflector is implemented on the buffer layer; a first deposition process in which an n-type cladding layer is deposited on the first reflector; a second deposition process in which an active layer is deposited on the n-type cladding layer; a third deposition process in which a p-type semiconductor layer is deposited on the active layer; a second implementing process in which a second reflector is implemented on the p-type semiconductor layer; an etching process in which etching proceeds vertically from the second reflector to the n-type cladding layer at both end portions so as to form a mesa structure; a second forming process in which a second electrode is formed on the second reflector; a coating process in which a passivation layer is applied to a side surface and/or an upper surface of each constituent of the light-emitting device; and a third forming process in which a through-hole is formed in the passivation layer and a first electrode is formed to electrically contact the buffer layer.

According to one aspect of the present invention, a light-emitting device comprises: a substrate; a buffer layer formed on the substrate; a first reflector implemented on the buffer layer and composed of a plurality of DBR pairs; an n-type cladding layer deposited on an upper surface of the first reflector and implemented with a semiconductor material doped with an n-type dopant to provide electrons; an active layer deposited on the n-type cladding layer and generating light by recombining provided electrons and holes; a p-type semiconductor layer deposited on the active layer and providing holes to the active layer; a second reflector implemented on the p-type semiconductor layer and composed of a plurality of DBR pairs; a metal layer implemented on a top-layer surface of the second reflector; a first electrode supplying power to the n-type cladding layer; a second electrode formed on the second reflector to supply power to the p-type semiconductor layer; and a passivation layer applied to a side surface and/or an upper surface of each constituent of the light-emitting device to protect each constituent from the outside.

According to one aspect of the present invention, the metal layer is implemented with a metal having a reflectance equal to or greater than a preset reference value.

According to one aspect of the present invention, the metal layer is implemented by forming an aluminum or silver metal layer and then sequentially depositing other metal layers such as nickel, titanium, chromium, and gold.

According to one aspect of the present invention, the metal layer reduces a thickness of the second reflector and facilitates formation of the second electrode.

According to one aspect of the present invention, a method of manufacturing a light-emitting device comprises: a first forming process in which a buffer layer is formed on a substrate; a first implementing process in which a first reflector is implemented on the buffer layer; a first deposition process in which an n-type cladding layer is deposited on the first reflector; a second deposition process in which an active layer is deposited on the n-type cladding layer; a third deposition process in which a p-type semiconductor layer is deposited on the active layer; a second implementing process in which a second reflector is implemented on the p-type semiconductor layer; a third implementing process in which a metal layer is implemented on the second reflector; an etching process in which etching proceeds vertically from the second reflector to the n-type cladding layer at both end portions so as to form a mesa structure; a second forming process in which a second electrode is formed on the second reflector; a coating process in which a passivation layer is applied to a side surface and/or an upper surface of each constituent of the light-emitting device; and a third forming process in which a through-hole is formed in the passivation layer and a first electrode is formed to electrically contact the buffer layer.

According to one aspect of the present invention, a light-emitting device comprises: a substrate; a buffer layer formed on the substrate; a first reflector implemented on the buffer layer and composed of a plurality of DBR pairs; an n-type cladding layer deposited on an upper surface of the first reflector and implemented with a semiconductor material doped with an n-type dopant to provide electrons; an active layer deposited on the n-type cladding layer and generating light by recombining provided electrons and holes; a p-type semiconductor layer deposited on the active layer and providing holes to the active layer; a second reflector implemented on the p-type semiconductor layer and composed of a plurality of DBR pairs; a first electrode implemented on an opposite surface of the substrate from a surface on which the buffer layer is formed, to supply power to the n-type cladding layer; a second electrode formed on the second reflector to supply power to the p-type semiconductor layer; and a passivation layer applied to a side surface and/or an upper surface of each constituent of the light-emitting device to protect each constituent from the outside.

According to one aspect of the present invention, the substrate is implemented with GaN, Al₂O₃, Si, SiC, ScAlMgO, LiAlO₂, MgAl₂O₄, or MoS₂.

According to one aspect of the present invention, the first reflector is formed by alternately combining: a thin-film layer of n-type GaN or n-type InGaN having a relatively high refractive index; and a thin-film layer of n-type AlGaN or InAlGaN having a relatively low refractive index.

According to one aspect of the present invention, each thin-film layer is implemented with a preset thickness.

According to one aspect of the present invention, a method of manufacturing a light-emitting device comprises: a first forming process in which a buffer layer is formed on a substrate; a first implementing process in which a first reflector is implemented on the buffer layer; a first deposition process in which an n-type cladding layer is deposited on the first reflector; a second deposition process in which an active layer is deposited on the n-type cladding layer; a third deposition process in which a p-type semiconductor layer is deposited on the active layer; a second implementing process in which a second reflector is implemented on the p-type semiconductor layer; an etching process in which etching proceeds vertically from the second reflector to the n-type cladding layer at both end portions so as to form a mesa structure; a second forming process in which a second electrode is formed on the second reflector; a coating process in which a passivation layer is applied to a side surface and/or an upper surface of each constituent of the light-emitting device; and a third forming process in which a first electrode is formed on an opposite surface of the substrate from a surface on which the buffer layer is formed.

According to one aspect of the present invention, because the light-emitting device includes nitride and oxide semiconductors and has a cavity structure, the light-emitting device may have high luminous efficiency and may output light with improved straightness.

### BRIEF DESCRIPTION OF THE DRAWINGS

FIG. 1 is a view showing a configuration of a light-emitting device according to a first embodiment of the present invention.

FIG. 2 is a view showing a configuration of a p-type semiconductor layer according to an embodiment of the present invention.

FIG. 3 is a graph showing reflection characteristics of a first reflector according to an embodiment of the present invention.

FIG. 4 is a graph showing reflection characteristics of a second reflector according to an embodiment of the present invention.

FIG. 5 is a view showing crystal lattice constants according to components of a semiconductor layer and an active layer according to an embodiment of the present invention.

FIG. 6 is a view showing a configuration of a light-emitting device according to a second embodiment of the present invention.

FIG. 7 is a view showing a configuration of a light-emitting device according to a third embodiment of the present invention.

FIGS. 8, 9, 10, 11, 12, 13, 14A, 14B, 15, 16, 17, and 18 are views showing a manufacturing process of a light-emitting device according to an embodiment of the present invention.

### DETAILED DESCRIPTION

The present disclosure may be changed in various ways and may have various embodiments. Specific embodiments are to be illustrated in the drawings and specifically described. It should be understood that the present disclosure is not intended to be limited to the specific embodiments, but includes all of changes, equivalents and/or substitutions included in the spirit and technical range of the present disclosure. Similar reference numerals are used for similar components while each drawing is described.

Terms, such as a first, a second, A, and B, may be used to describe various components, but the components should not be restricted by the terms. The terms are used to only distinguish one component from another component. For example, a first component may be referred to as a second component without departing from the scope of rights of the present disclosure. Likewise, a second component may be referred to as a first component. The term “and/or” includes a combination of a plurality of related and described items or any one of a plurality of related and described items.

When it is described that one component is “connected” or “coupled” to the other component, it should be understood that one component may be directly connected or coupled to the other component, but a third component may exist between the two components. In contrast, when it is described that one component is “directly connected to” or “directly coupled to” the other component, it should be understood that a third component does not exist between the two components.

Terms used in this application are used to only describe specific embodiments and are not intended to restrict the present disclosure. An expression of the singular number includes an expression of the plural number unless clearly defined otherwise in the context. In this specification, a term, such as “include” or “have”, is intended to designate the presence of a characteristic, a number, a step, an operation, a component, a part or a combination of them, and should be understood that it does not exclude the existence or possible addition of one or more other characteristics, numbers, steps, operations, components, parts, or combinations of them in advance.

All terms used herein, including technical terms or scientific terms, have the same meanings as those commonly understood by a person having ordinary knowledge in the art to which the present disclosure pertains, unless defined otherwise in the specification.

Terms, such as those defined in commonly used dictionaries, should be construed as having the same meanings as those in the context of a related technology, and are not construed as ideal or excessively formal meanings unless explicitly defined otherwise in the application.

Furthermore, each construction, process, procedure, or method included in each embodiment of the present disclosure may be shared within a range in which the constructions, processes, procedures, or methods do not contradict each other technically.

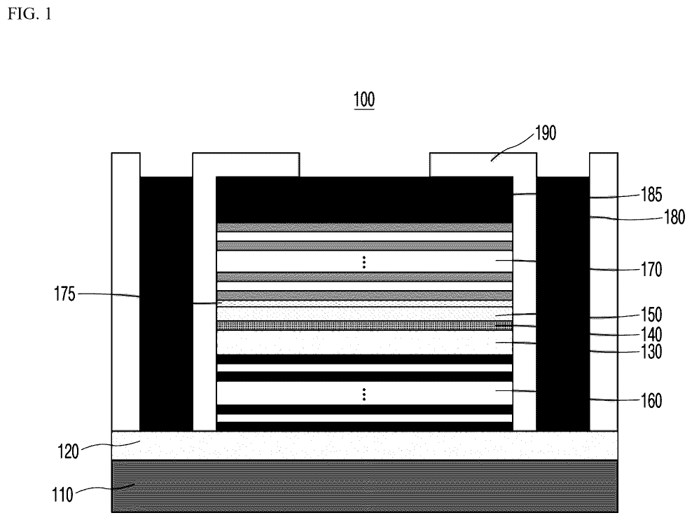

FIG. 1 is a view illustrating a configuration of a light-emitting device according to a first embodiment of the present invention.

Referring to FIG. 1, a light-emitting device (100) according to the first embodiment of the present invention includes a substrate (110), a buffer layer (120), an n-type cladding layer (130), an active layer (140), a p-type semiconductor layer (150), a first reflector (160), a second reflector (170), a protective layer (175), a first electrode (180), a second electrode (185), and a passivation layer (190).

The light-emitting device (100) is a light-emitting device in the form of an LED or LD having a cavity structure. Unlike conventional light-emitting devices, the light-emitting device (100) can have high luminous efficiency and can output light having improved straightness. Since the light-emitting device includes a zinc oxide (ZnO)-based oxide semiconductor therein, internal stress may be reduced, thereby improving luminous efficiency. In addition, the light-emitting device (100) may output light having improved straightness by including a cavity structure; however, unlike a VCSEL, it may not output a lasing beam.

The substrate (110) provides a space in which the remaining components of the light-emitting device (100) can be formed. The substrate (110) provides a space such that the remaining components of the light-emitting device (100) can be formed on one surface thereof or on both surfaces thereof. The substrate may be made of GaN, Al₂O₃, Si, SiC, ScAlMgO, LiAlO₂, MgAl₂O₄, MoS₂, or the like, which allows epitaxial deposition, and may be made of GaN doped with an n-type dopant or the like.

The buffer layer (120) is formed on the substrate (110) and allows the first reflector (160) to grow on an upper surface thereof.

The n-type cladding layer (130) is deposited above the buffer layer (120) in a vertical direction (more specifically, on an upper surface of the first reflector) and is made of a semiconductor material doped with an n-type dopant to provide electrons to the active layer (140). The n-type cladding layer (130) may be deposited on the first reflector (160), which will be described later, by epitaxial single-crystal deposition. The n-type cladding layer (130) may be made of n-type gallium nitride (n-GaN), but is not limited thereto, and may be replaced with n-type InGaN, n-type AlGaN, or n-type AlInGaN, or a combination thereof.

The active layer (140) is deposited on the n-type cladding layer (130), and electrons provided by the n-type cladding layer (130) and holes provided by the p-type semiconductor layer (150) meet and recombine in the active layer (140) to generate light. The active layer (140) includes a well layer (not illustrated) having a relatively small energy bandgap and a barrier layer (not illustrated) having a relatively large energy bandgap. The active layer (140) may be made of InGaN layers having different In concentrations, InGaN/GaN layers, GaN/AlGaN layers, or AlGaN layers having different Al concentrations, and may also be made of a combination thereof. The active layer (140) includes two or more barrier layers and one or more well layers.

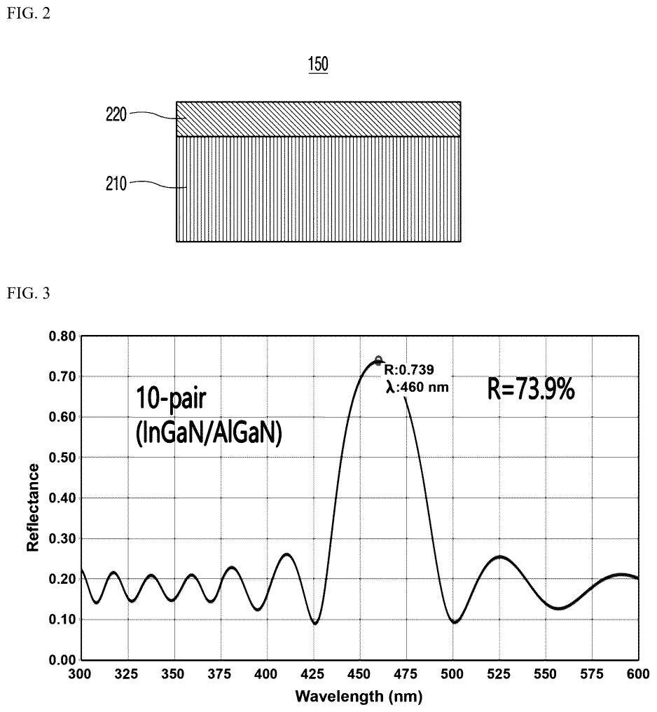

The p-type semiconductor layer (150) is deposited on the active layer (140) and provides holes to the active layer (140). Since the p-type semiconductor layer (150) is implemented in the structure shown in FIG. 2, internal strain may be minimized so that the light-emitting device (100) has high luminous efficiency.

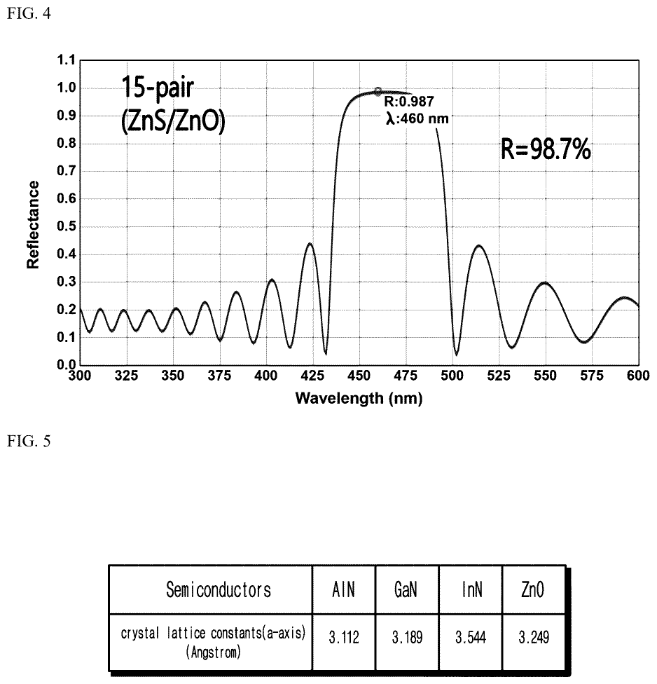

FIG. 2 is a view illustrating a configuration of a p-type semiconductor layer according to an embodiment of the present invention, and FIG. 5 is a view illustrating crystal lattice constants according to components of semiconductor layers and an active layer according to an embodiment of the present invention.

Referring to FIG. 2, the p-type semiconductor layer (150) according to an embodiment of the present invention may include a p-type cladding layer (210) and a p-type oxide layer (220).

The p-type cladding layer (210) is deposited directly on the active layer (140). The p-type cladding layer (210) is made of a semiconductor material doped with a p-type dopant and provides delivered holes to the active layer (140). The p-type cladding layer (210) may be deposited on the active layer (140) by epitaxial single-crystal deposition. The p-type cladding layer (210) may be made of p-type gallium nitride (p-GaN) as in the conventional case, but is not limited thereto, and may be replaced with p-type InGaN, p-type AlGaN, or p-type AlInGaN, or a combination thereof.

The p-type oxide layer (220) is deposited on the p-type cladding layer (210), thereby alleviating internal pressure (strain) that may occur between the active layer (140) and the p-type cladding layer (210) and improving a transfer rate of holes.

The p-type oxide layer (220) is made of a zinc oxide (ZnO)-based compound and may be deposited on the p-type cladding layer (210) by epitaxial single-crystal deposition, chemical vapor deposition (CVD), molecular beam epitaxy (MBE), pulsed laser deposition (PLD), or a hybrid thereof. The p-type oxide layer (220) may be stacked on the p-type cladding layer (210) to have a thickness between 10 nm and 1000 nm.

The p-type oxide layer (220) may be made of zinc oxide (ZnO) having a hexagonal crystal structure, or may be made of an oxide including zinc (Zn) and including group II elements and group VI elements in the periodic table. For example, the internal-pressure relaxation layer (220) may be made of ZnO, BeZnO, MgZnO, BeMgZnO, ZnSO, ZnSeO, ZnSSeO, ZnCdO, or ZnCdSeO. Since the p-type oxide layer (220) implemented as described above has a larger lattice constant and a higher hole concentration than the p-type cladding layer (210), it can reduce internal pressure existing between the active layer (140) and the p-type cladding layer (210), as can be confirmed in FIG. 5.

Referring to FIG. 5, it can be confirmed that AlN, GaN, and InN all have different crystal lattice constants. Due to such differences in crystal lattice constants, internal pressure occurs between the active layer (140) and the p-type cladding layer (210). Since the p-type oxide layer (220) has a larger lattice constant and a higher hole concentration than the p-type cladding layer (210), it alleviates internal pressure existing between the active layer (140) and the p-type cladding layer (210).

When internal pressure between the active layer (140) and the p-type cladding layer (210) decreases, it can be confirmed that the light-emitting device (100) has a relatively small flat-band voltage and piezoelectric voltage and thus has a relatively wide depletion width. Accordingly, injection of holes into the active layer (140) becomes easier, and internal quantum efficiency may also be significantly increased.

In order to inject more holes into the active layer (140), the p-type oxide layer (220) may be doped with p-type impurities at a predetermined concentration or may generate Zn vacancies without impurity doping. The p-type oxide layer (220) may be doped with p-type impurities within a predetermined concentration range. The doped impurities may be p-type acceptor impurities and may be, for example, one or more of H, Li, Na, K, Rb, Cs, Fr, Cu, Ag, N, P, As, Sb, and Bi. Such p-type acceptor impurities may be doped into a zinc oxide-based compound to form the p-type oxide layer (220), and the p-type acceptor impurities may be doped at the predetermined concentration. The predetermined concentration may be 1×10¹⁷ to 1×10²⁰ atoms/cm³, and more preferably 5×10¹⁸ to 5×10¹⁹ atoms/cm³.

Meanwhile, the p-type oxide layer (220) may generate Zn vacancies without doping impurities. After an undoped zinc oxide-based compound is deposited on a surface of the p-type cladding layer, it may be heat-treated in a gas atmosphere containing oxygen to form the p-type oxide layer (220). The heat treatment may be performed at 400° C. to 700° C., more preferably 450° C. to 550° C., for 1 to 600 minutes, more preferably 10 to 60 minutes, in the corresponding atmosphere. When the zinc oxide-based compound is heat-treated in the above-described atmosphere, a phenomenon occurs in which metal atoms constituting the zinc oxide-based compound, for example, zinc, become deficient. Through the above-described process, the p-type oxide layer (220) can minimize internal pressure that may occur between the active layer (140) and the p-type cladding layer (210) and facilitate injection of holes into the active layer (140).

Referring again to FIG. 1, the first reflector (160) is formed on the buffer layer (120) and may be made of a semiconductor material doped with an n-type dopant. The first reflector (160) includes a plurality of DBR (Distributed Bragg Reflector, or “distributed Bragg reflector”) pairs. The first reflector (160) may have a superlattice formed by alternately coupling an n-type GaN or n-type InGaN thin-film layer having a relatively high refractive index and an n-type AlGaN or InAlGaN thin-film layer having a relatively low refractive index.

Each thin-film layer alternately coupled in the first reflector (160) has a predetermined thickness. Here, the predetermined thickness is determined according to a wavelength of light to be reflected (light output from the active layer) and may be a value (λ/4n) obtained by dividing the wavelength (λ) of the light by four times the refractive index (n) of the thin-film layer, or an odd multiple thereof. Since each thin-film layer in the first reflector (160) is implemented to have the predetermined thickness, the light can be reflected even with an optimal number of layers.

The second reflector (170) is formed on the p-type semiconductor layer (150), more specifically on the p-type oxide layer (220), and may be made of a semiconductor material doped with a p-type dopant. The second reflector (170) also includes a plurality of DBR pairs. The second reflector (170) may have a superlattice formed by coupling a first thin-film layer and a second thin-film layer so as to have low electrical resistance and not absorb light to be reflected (light output from the active layer). The first thin-film layer is implemented to have an energy band equal to or greater than a predetermined reference value and to have a refractive index equal to or greater than a predetermined reference value in a wavelength band of the light to be reflected (light output from the active layer). The second thin-film layer is implemented to have a refractive index equal to or less than a predetermined reference value in the wavelength band of the light to be reflected (light output from the active layer). Here, the first thin-film layer may be made of a component including zinc (Zn) or magnesium (Mg) and including group II elements and group VI elements in the periodic table, and may be made of ZnSe, ZnS, ZnTe, MgS, ZnSeS, ZnSeTe, ZnSTe, ZnMgSe, ZnMgS, ZnMgSeTe, ZnMgSTe, ZnMgSeS, or the like. The second thin-film layer may be made of ITO, IGZO, ZnO, MgO, ZnMgO, Ga₂O₃, or the like.

Each thin-film layer in the second reflector (170) may also be implemented to have the predetermined thickness, like the thin-film layers in the first reflector (160).

The first reflector (160) and the second reflector (170) have reflection characteristics as shown in FIGS. 3 and 4.

FIG. 3 is a graph illustrating reflection characteristics of the first reflector according to an embodiment of the present invention, and FIG. 4 is a graph illustrating reflection characteristics of the second reflector according to an embodiment of the present invention.

Referring to FIG. 3, the first reflector (160) has reflectance of 50% to 90%, and more preferably 60% to 80%.

In contrast, referring to FIG. 4, the second reflector (170) has reflectance of 90% or more, and more preferably 95% or more.

Referring again to FIG. 1, as described above, the first reflector (160) and the second reflector (170) are included, and thin-film layers in the two reflectors are implemented with mutually different components—one with a nitride-based component and the other with a zinc-or magnesium-based component—so that the n-type cladding layer (130), the active layer (140), and the p-type semiconductor layer (150) form a cavity structure. In this case, a total thickness of the layers (130 to 150) forming the cavity structure is determined according to a wavelength of light output from the active layer (140) and may be a value (λ/2n) obtained by dividing the wavelength (λ) of the light by twice the refractive index (n) of the material forming the cavity structure, or an integer multiple thereof. Since the first reflector (160) and the second reflector (170) are included and the cavity structure has the above-described thickness, only straight-propagating light is resonantly amplified, and thus the light output from the light-emitting device (100) can have straightness without dispersion.

The protective layer (175) is deposited on the p-type semiconductor layer (150) to protect the p-type semiconductor layer (150) from an external environment and, together with the p-type oxide layer (220)), enables the second reflector (170) to grow on the p-type semiconductor layer (150). The protective layer (175) may be made of ITO, a zinc oxide-based compound, or an oxide including zinc (Zn) and including group II elements and group VI elements in the periodic table. The protective layer (175) is implemented with the above-described component on the p-type semiconductor layer (150) and is implemented as a transparent thin-film layer.

The protective layer (175) is deposited on an upper surface of the p-type oxide layer (220), thereby protecting the p-type oxide layer (220) from various chemicals used in a manufacturing process of the light-emitting device (100) and uniformly and efficiently injecting holes into the entire region of the p-type semiconductor layer (150) during device operation.

The protective layer (175), together with the p-type oxide layer (220), enables the second reflector (170) having a different composition to grow on the p-type semiconductor layer (150). The p-type semiconductor layer (150), more specifically the p-type cladding layer (210), is implemented with a gallium nitride-based compound as described above, whereas the second reflector (170) is implemented with a zinc oxide-based compound or the like. Since the two have different compositions, growth of the second reflector (170) may be difficult. To prevent such a problem, the protective layer (175) is positioned between the two so that the second reflector (170) having a different composition can grow on the p-type semiconductor layer (150).

In addition, the protective layer (175) prevents the first reflector (160) or the respective cladding layers (130, 210), which are made of a gallium nitride-based compound, from being exposed to an oxygen atmosphere. Since the protective layer (175) is made of an oxide or ITO as described above, no change in composition or characteristics occurs even when exposed to an oxygen atmosphere. In contrast, when the above-described components made of a gallium nitride-based compound are exposed to an oxygen atmosphere, their composition or characteristics change. During deposition or growth of the p-type oxide layer (220) or the second reflector (170), exposure to an oxygen atmosphere may occur, and the protective layer (175) deposited at the above-described position protects the first reflector (160) or the respective cladding layers (130, 210), which are made of a gallium nitride-based compound, from oxygen.

The first electrode (180) is in electrical contact with a surface of the buffer layer (120) exposed by etching, thereby supplying power to the n-type cladding layer (130).

The second electrode (185) is formed on the second reflector (170) and supplies power to the p-type semiconductor layer (150). As described above, the second reflector (170) has a structure in which the first thin-film layer and the second thin-film layer are alternately coupled. In this case, since the first thin-film layer and the second thin-film layer have excellent electrical conductivity (low electrical resistance), the second reflector (170) can directly transfer power supplied from the second electrode (185) to the p-type semiconductor layer (150) without implementing a separate component or an additional structure. Accordingly, the second electrode (185) is formed directly on the second reflector (170) to supply power to the p-type semiconductor layer (150).

The passivation layer (190) is applied to side surfaces of respective components in the light-emitting device (100), more specifically side surfaces of the n-type cladding layer (130) to the second electrode (185), and upper surfaces of the buffer layer (120) and the second electrode (185), thereby protecting the respective components (120 to 185) from the outside. Meanwhile, the passivation layer (190) includes a through-hole so that the first electrode (180) can be in electrical contact with the surface of the buffer layer (120) to deliver power.

Since the light-emitting device (100) includes nitride and oxide semiconductors and has a cavity structure, it has high luminous efficiency and can output light having improved straightness.

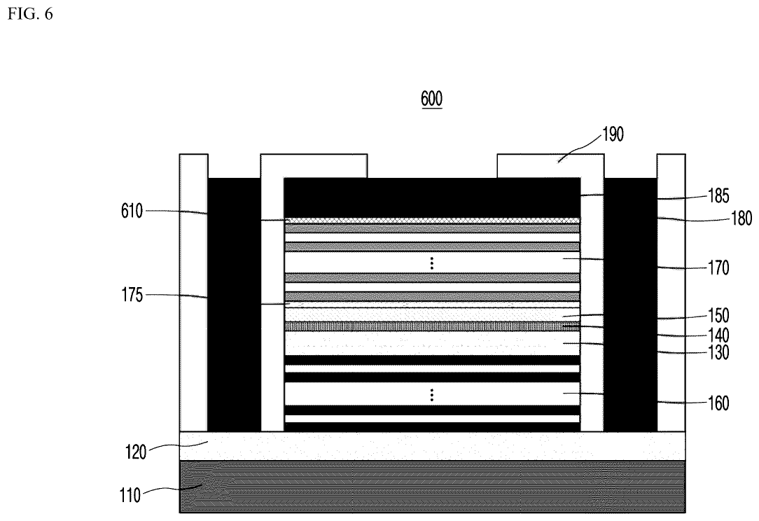

FIG. 6 is a view illustrating a configuration of a light-emitting device according to a second embodiment of the present invention.

Referring to FIG. 6, a light-emitting device (600) according to the second embodiment of the present invention may further include a metal layer (610).

The metal layer (610) 2 is implemented with a metal having excellent reflectance (reflectance equal to or greater than a predetermined reference value) on an uppermost-layer surface of the second reflector (170). For example, the metal layer (610) may be made of aluminum or silver, or may be implemented by forming one layer of aluminum or silver and then additionally depositing another layer such as nickel (Ni), titanium (Ti), chromium (Cr), gold (Au), or the like. Since the metal layer (610) is implemented with a metal having excellent reflectance on the uppermost-layer surface of the second reflector (170), it can simultaneously perform the role of the second reflector (170), thereby relatively reducing a thickness of the second reflector (170). In addition, the metal layer (610) can facilitate formation of the second electrode (185).

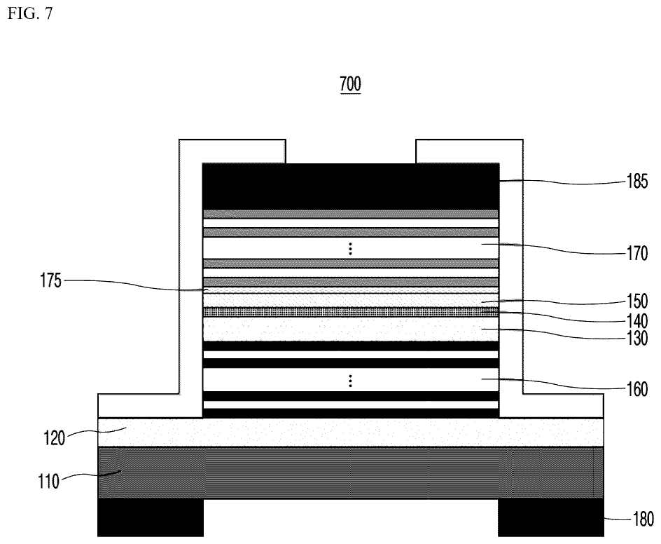

FIG. 7 is a view illustrating a configuration of a light-emitting device according to a third embodiment of the present invention.

Unlike the first electrode (180) in the light-emitting device (100), the first electrode (180) in the light-emitting device (700) may be implemented on a surface of the substrate (110) opposite to a surface on which the buffer layer (120) is formed. The first electrode (180) supplies power to the n-type cladding layer (130) through the substrate (110) or the like from the opposite surface of the substrate (110).

Meanwhile, since the first electrode (180) is implemented on the opposite surface of the substrate (110), the passivation layer (190) may not include a through-hole, and prevents side surfaces or upper surfaces of respective components in the light-emitting device (100), more specifically the n-type cladding layer (130) to the second reflector (170), from being exposed to the outside.

FIGS. 8 to 18 are views illustrating a manufacturing process of a light-emitting device according to an embodiment of the present invention.

Referring to FIG. 8, a buffer layer (120) is formed on the substrate (110).

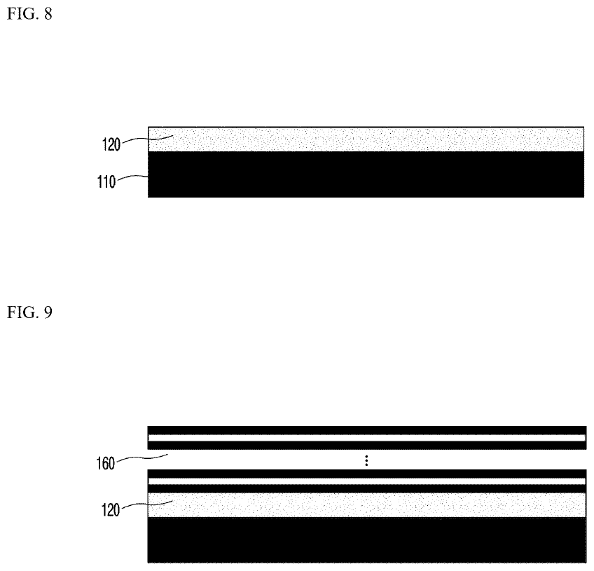

Referring to FIG. 9, the first reflector (160) is formed on the buffer layer (120).

Referring to FIG. 10, an n-type cladding layer (130) is deposited on the first reflector (160).

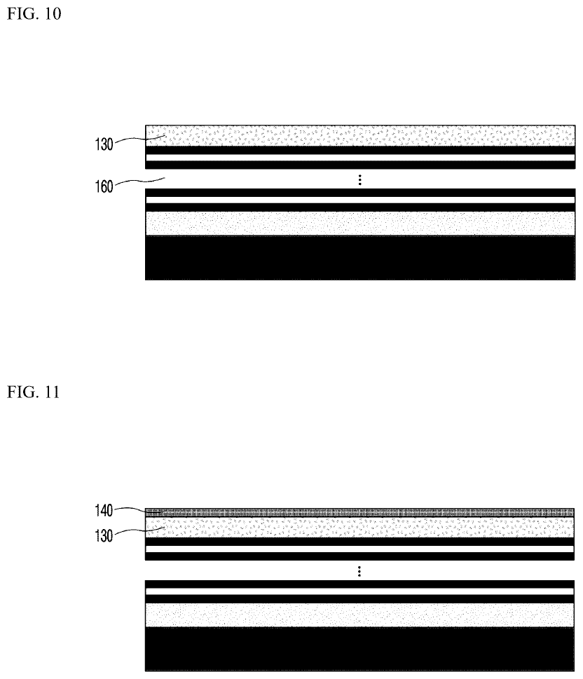

Referring to FIG. 11, an active layer (140) is deposited on the n-type cladding layer (130).

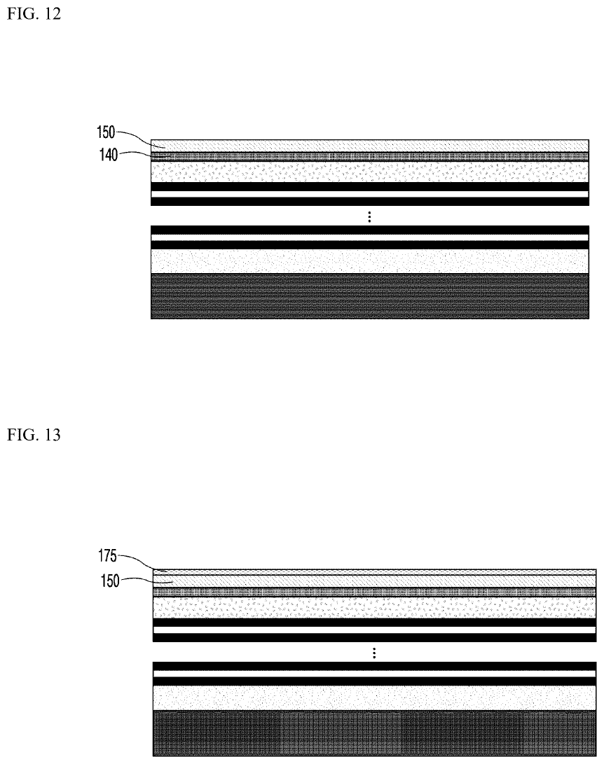

Referring to FIG. 12, a p-type semiconductor layer (150) is deposited on the active layer (140).

Referring to FIG. 13, a protective layer (175) is deposited on the p-type semiconductor layer (150).

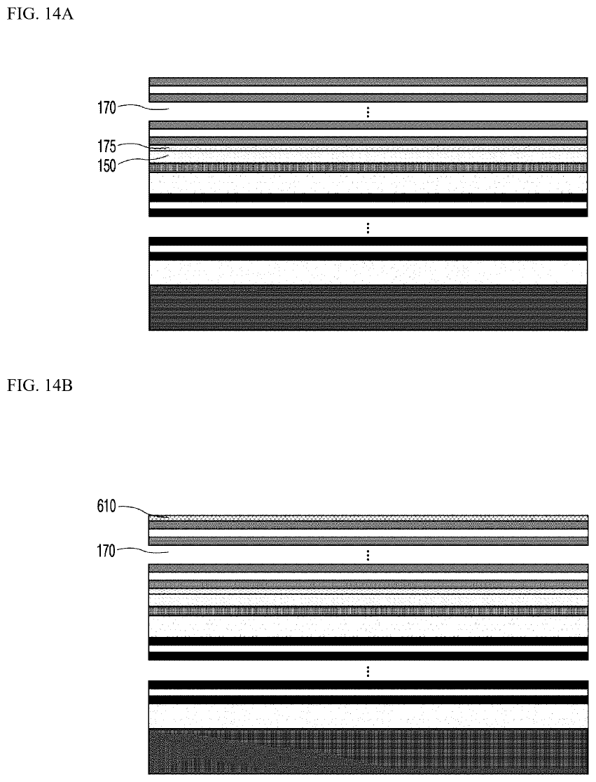

Referring to FIG. 14A, the second reflector (170) is formed on the protective layer (175).

Meanwhile, in the case of the light-emitting device (600), as illustrated in FIG. 14B, the metal layer (610) is additionally formed on the second reflector (170).

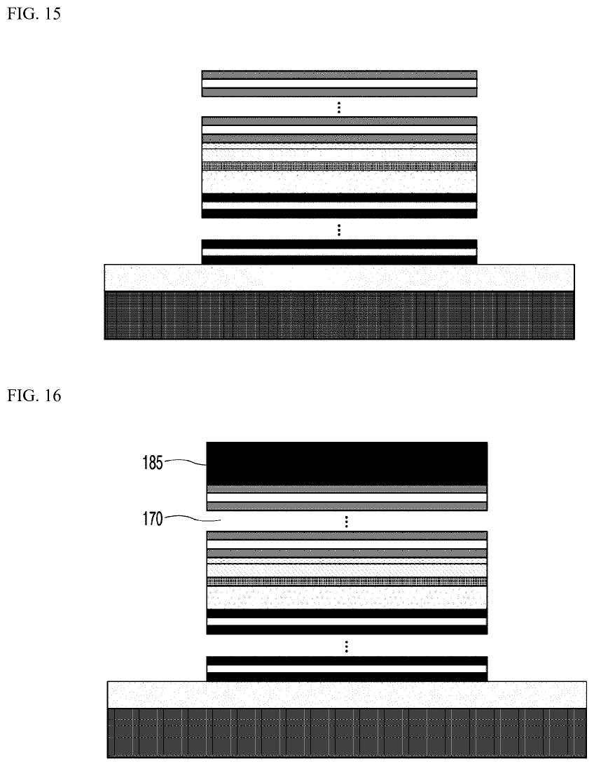

Referring to FIG. 15, etching is performed in a vertical direction at both ends from the second reflector (170) or the metal layer (610) to the n-type cladding layer (130). Accordingly, a mesa structure may be formed in the n-type cladding layer (130) to the second reflector (170) or the metal layer (610).

Referring to FIG. 16, the second electrode (185) is formed on the second reflector (170) or the metal layer (610).

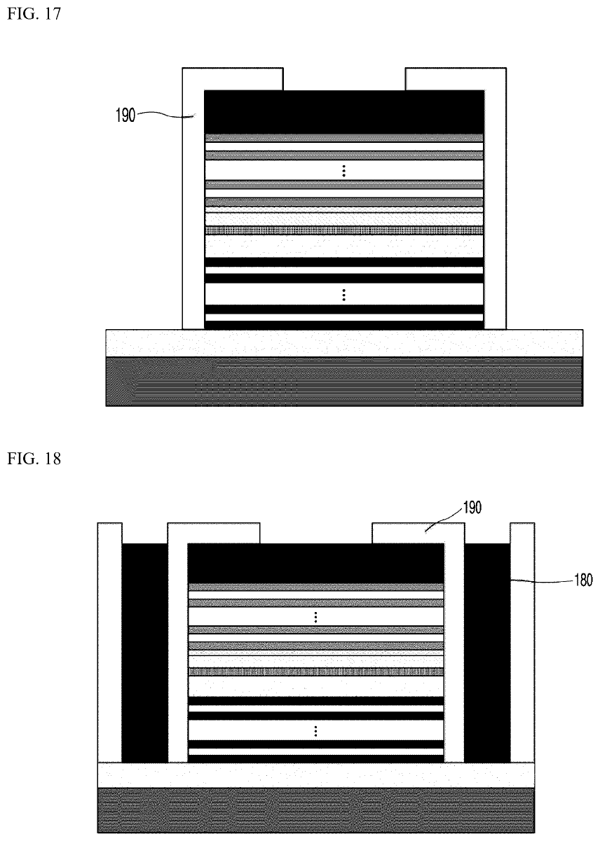

Referring to FIG. 17, the passivation layer (190) is applied to side surfaces of the n-type cladding layer (130) to the second electrode (185), and upper surfaces of the buffer layer (120) and the second electrode (185).

Referring to FIG. 18, a through-hole is formed in the passivation layer (190), and the first electrode (180) is formed to be in electrical contact with the surface of the buffer layer (120).

Meanwhile, in the case of the light-emitting device (700), instead of forming a through-hole in the passivation layer (190), the first electrode (180) is formed on the surface of the substrate (110) opposite to the buffer-layer-formed surface.

The above description is merely a description of the technical spirit of the present embodiment, and those skilled in the art may change and modify the present embodiment in various ways without departing from the essential characteristic of the present embodiment. Accordingly, the embodiments should not be construed as limiting the technical spirit of the present embodiment, but should be construed as describing the technical spirit of the present embodiment. The technical spirit of the present embodiment is not restricted by the embodiments. The range of protection of the present embodiment should be construed based on the following claims, and all of technical spirits within an equivalent range of the present embodiment should be construed as being included in the scope of rights of the present embodiment.

What is claimed is:

1. A light emitting device comprising:
a substrate;
a buffer layer formed on the substrate;
a first reflector formed on the buffer layer and comprising a plurality of DBR (Distributed Bragg Reflector) pairs;
an n-type cladding layer deposited on an upper surface of the first reflector and implemented with a semiconductor material doped with an n-type dopant to provide electrons;
an active layer deposited on the n-type cladding layer and configured to generate light by recombining the provided electrons and holes;
a p-type semiconductor layer deposited on the active layer and configured to provide holes to the active layer;
a second reflector formed on the p-type semiconductor layer and comprising a plurality of DBR pairs;
a first electrode electrically contacting the buffer layer and supplying power to the n-type cladding layer;
a second electrode formed on the second reflector and supplying power to the p-type semiconductor layer; and
a passivation layer applied to a side surface or an upper surface of each component of the light emitting device to protect each component from an external environment.

2. The light emitting device of claim 1, further comprising a protective layer deposited on the p-type semiconductor layer to protect the p-type semiconductor layer from an external environment.

3. The light emitting device of claim 1, wherein the p-type semiconductor layer comprises:
a p-type cladding layer deposited directly on the active layer and implemented with a semiconductor material doped with a p-type dopant to provide holes to the active layer; and
a p-type oxide layer deposited on the p-type cladding layer, configured to alleviate internal stress that may occur between the active layer and the p-type cladding layer and to improve hole transport efficiency.

4. The light emitting device of claim 3, wherein the p-type cladding layer is implemented with p-type GaN, p-type InGaN, p-type AlGaN, p-type AlInGaN, or a combination thereof.

5. The light emitting device of claim 3, wherein the p-type oxide layer is implemented with zinc oxide (ZnO), or an oxide including zinc (Zn) and including Group 2 elements and Group 6 elements in the periodic table.

6. A light emitting device comprising:
a substrate;
a buffer layer formed on the substrate;
a first reflector formed on the buffer layer and comprising a plurality of DBR (Distributed Bragg Reflector) pairs;
an n-type cladding layer deposited on an upper surface of the first reflector and implemented with a semiconductor material doped with an n-type dopant to provide electrons;
an active layer deposited on the n-type cladding layer and configured to generate light by recombining the provided electrons and holes;
a p-type semiconductor layer deposited on the active layer and configured to provide holes to the active layer;
a second reflector formed on the p-type semiconductor layer and comprising a plurality of DBR pairs;
a metal layer formed on an outermost surface of the second reflector;
a first electrode supplying power to the n-type cladding layer;
a second electrode formed on the second reflector and supplying power to the p-type semiconductor layer; and
a passivation layer applied to a side surface or an upper surface of each component of the light emitting device to protect each component from an external environment.

7. The light emitting device of claim 6, wherein the metal layer is implemented with a metal having a reflectance equal to or greater than a predetermined reference value.

8. The light emitting device of claim 7, wherein the metal layer is implemented with aluminum or silver.

9. The light emitting device of claim 6, wherein the metal layer reduces a thickness of the second reflector and facilitates formation of the second electrode.

10. A light emitting device comprising:
a substrate;
a buffer layer formed on the substrate;
a first reflector formed on the buffer layer and comprising a plurality of DBR (Distributed Bragg Reflector) pairs;
an n-type cladding layer deposited on an upper surface of the first reflector and implemented with a semiconductor material doped with an n-type dopant to provide electrons;
an active layer deposited on the n-type cladding layer and configured to generate light by recombining the provided electrons and holes;
a p-type semiconductor layer deposited on the active layer and configured to provide holes to the active layer;
a second reflector formed on the p-type semiconductor layer and comprising a plurality of DBR pairs;
a first electrode formed on a surface of the substrate opposite to a surface on which the buffer layer is formed, and supplying power to the n-type cladding layer;
a second electrode formed on the second reflector and supplying power to the p-type semiconductor layer; and
a passivation layer applied to a side surface or an upper surface of each component of the light emitting device to protect each component from an external environment.

11. The light emitting device of claim 1, claim 6, or claim 10, wherein the substrate is implemented with GaN, Al₂O₃, Si, SiC, ScAlMgO, LiAlO₂, MgAl₂O₄, or MoS₂.

12. The light emitting device of claim 1, claim 6, or claim 10, wherein the first reflector is formed by alternately coupling:
an n-type GaN or n-type InGaN thin film layer having a relatively high refractive index; and
an n-type AlGaN or n-type InAlGaN thin film layer having a relatively low refractive index.

13. The light emitting device of claim 12, wherein each thin film layer has a predetermined thickness.
